(19) United States
(12) Patent Application Publication
(10) Pub. No.: US 2024/0080986 A1
(43) Pub. Date: Mar. 7, 2024

(54) CONTAMINANT SHIELD FOR AN OSCILLATOR

(71) Applicant: Apple Inc., Cupertino, CA (US)

(72) Inventors: David A. Karol, San Francisco, CA (US); Yaodong Wang, San Jose, CA (US); Obinna O. Onyemepu, Campbell, CA (US); Zhong J. Ma, Mountain View, CA (US); Harshavardhan Reddy Abbeydoddi Bolla, Santa Clara, CA (US); Robert Hrabchak, Chicago, IL (US)

(21) Appl. No.: 18/450,701

(22) Filed: Aug. 16, 2023

Related U.S. Application Data
(60) Provisional application No. 63/404,028, filed on Sep. 6, 2022.

(51) Int. Cl. H05K 1/18; H05K 3/00

(52) U.S. Cl. CPC H05K 1/181; H05K 3/0011; H05K 2201/10015; H05K 2201/10151; H05K 2201/10431

(57) ABSTRACT

The present disclosure relates to a contaminant shield system. The contaminant shield system may surround an electronic device, such as a local oscillator (e.g., a crystal oscillator), to prevent contamination of the electronic device via coupling material (e.g., under-fill material) creep or wicking. The contaminant shield system includes multiple walls and at least one wall includes a pick-and-place feature that facilitates positioning of the contaminant shield system during assembly of a circuit board that includes the contaminant shield system.

### CROSS-REFERENCE TO RELATED APPLICATIONS

This application claims priority to U.S. Provisional Application No. 63/404,028, filed Sep. 6, 2022, entitled “Contaminant Shield for an Oscillator,” the disclosure of which is incorporated by reference in its entirety for all purposes.

### BACKGROUND

The present disclosure relates generally to contamination shielding and space-saving features on a circuit board.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

During the assembly of electronic devices, different types of electronic components may be coupled to a circuit board. At least in some instances, it may be advantageous to provide a coupling material such as an under-fill material, a conformal coating, or encapsulation material, to provide certain benefits such as improving the coupling between the electronic components and the circuit board. However, the coupling material may contaminate certain electronic components such as a radio frequency (RF) related capacitor and/or a local oscillator, such as a crystal oscillator. Such contamination may cause these electronic components to operate in an unexpected or otherwise undesirable manner.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

This disclosure is directed to techniques for preventing contamination of a local oscillator, while providing space-saving benefits, such as reducing the footprint of the local oscillator and one or more electronic components on a circuit board. As mentioned above, certain coupling materials (e.g., under-fill materials, conformal coating materials, and encapsulation materials) may provide benefits such as improved coupling between electronic components in a circuit board. However, the coupling materials may also adversely affect the operation of other electronic components, such as a land grid array (LGA), a local oscillator, a ball grid array (BGA), a temperature sensing crystal (XTAL), a thermally compensated crystal oscillator (TCXO), and/or a radio frequency (RF) related capacitor. For example, a local oscillator (e.g., a crystal oscillator) produces an oscillating electronic signal (e.g., a clock signal) that is used for a variety of operations performed using larger electronic devices. In certain arrangements of the circuit board, the local oscillator may be disposed near the electronic components that may be provided with the coupling materials discussed above. As such, the local oscillator may be susceptible to contamination via coupling material creep or wicking (e.g., whereby excess coupling material deposited onto the circuit board may flow outwards and approach and, at least in some instances, contact other electronic components) and/or splatter (e.g., whereby the coupling material may splash and inadvertently deposit coupling material onto the local oscillator that is within a threshold range of circuit board components that are coupled to the circuit board via the coupling material). As referred to herein, contamination refers to an unintended application of coupling material to an electronic component that may adversely affect operation of the electronic component. For example, if the local oscillator is contaminated with the coupling material, the contamination may cause a clock drift in the oscillating electronic signal generated by the local oscillator. As such, the contaminated local oscillator may cause further issues, such as causing a call to be dropped (e.g., in embodiments where the local oscillator is used in a phone) and/or causing in unintentional reboot of the electronic device.

At least in some instances, there may be physical constraints (e.g., dimension constraints, such as a limited amount of area on the circuit board) that prevent moving the local oscillator to a location far away enough from where the coupling material is deposited. While a soldering layer may be disposed around the local oscillator to block coupling material creep or wicking onto the local oscillator, the coupling material may, at least in some instances, splatter onto the local oscillator, and thus contaminate the local oscillator. Further, while it may be advantageous to arrange certain electronic components (e.g., a capacitor) in between the local oscillator and the circuit board components (e.g., coupled to the circuit board via the coupling material) to block coupling material creep or wicking, the arrangement of the electronic components may reduce an amount of usable area on the circuit (e.g., increase the footprint of the electronic components).

As such, embodiments disclosed herein provide various apparatuses and techniques to prevent contamination of certain electronic components that may be sensitive to contamination from the coupling material, such as a land grid array (LGA), a local oscillator, a ball grid array (BGA), a temperature sensing crystal (XTAL), a thermally compensated crystal oscillator (TCXO), and/or a radio frequency (RF) related capacitor, while also providing space-saving features, such as reducing the footprint of these electronic components and other electronic components used to block the flow of under-fill material. To do so, embodiments disclosed herein include a contaminant shield system. In general, the contaminant shield system includes a contaminant shield structure that substantially surrounds the local oscillator, or other electronic components as discussed herein, to prevent coupling material creep or wicking, while also having a sufficient height to block coupling material splatter. Additionally, it should be noted that if the contaminant shield has a sufficient height, the electronic components proximate to the contaminant shield (e.g., in particular orientations or arrangements) that prevent coupling material creep or wicking may be moved to different locations. Accordingly, the contaminant shield may provide space-saving features, such as reducing a footprint of the local oscillator and other electronic components on the circuit board. In some embodiments, the contaminant shield may be formed of a conductive material that forms an electromagnetic interference (EMI) shield (e.g., a Faraday cage) about at least a portion of the local oscillator. The contaminant shield structure also includes one or more pick-and-place features on one or more walls of the contaminant shield. The pick-and-place features generally have suitable dimensions (e.g., a suitable thickness) along a longitudinal axis or transverse axis, such as a wall with a particular thickness, a tab, and/or a lid, that facilitate the positioning of the contaminant shield during assembly and/or ease of integration with assembly processes.

### BRIEF DESCRIPTION OF THE DRAWINGS

Various aspects of this disclosure may be better understood upon reading the following detailed description and upon reference to the drawings in which:

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is an aerial view of a circuit board of the electronic device of FIG. 1 having a local oscillator, circuit board components, and other electronic components, according to embodiments of the present disclosure;

FIG. 6 is a perspective view of a first example of a shielded oscillator system including a local oscillator and a contaminant shield, according to embodiments of the present disclosure;

FIG. 7 is a perspective view of a second example of a shielded oscillator system including a local oscillator and a contaminant shield with a press lid, according to embodiments of the present disclosure;

FIG. 8 is a perspective view of a third example of a shielded oscillator system including a local oscillator and a contaminant shield with a press tab, according to embodiments of the present disclosure;

FIG. 9 is a perspective view of a first example of a shielded oscillator system including a local oscillator and a contaminant shield surrounding additional electronic components, according to embodiments of the present disclosure;

FIG. 10 is a schematic diagram of the total length of one or more electronic components, according to embodiments of the present disclosure; and

FIG. 11 is a flow chart of a method for assembling the shield oscillator system, according to embodiments of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on.

This disclosure is directed to preventing contamination of a local oscillator, while providing space-saving benefits, such as reducing the footprint of the local oscillator and one or more electronic components on a circuit board. As such, embodiments disclosed herein provide various apparatuses and techniques to prevent contamination of a local oscillator (e.g., a crystal oscillator), while also providing space-saving features, such as reducing the footprint of the local oscillator and other electronic components used to block the flow of under-fill material. It should be noted that the disclosed various apparatuses and techniques may prevent contamination of other components that may be adversely affected by contamination, such as a land grid array (LGA), a local oscillator, a ball grid array (BGA), a temperature sensing crystal (XTAL), a thermally compensated crystal oscillator (TCXO), a gyroscope, a radio frequency (RF) related capacitor, and so on.

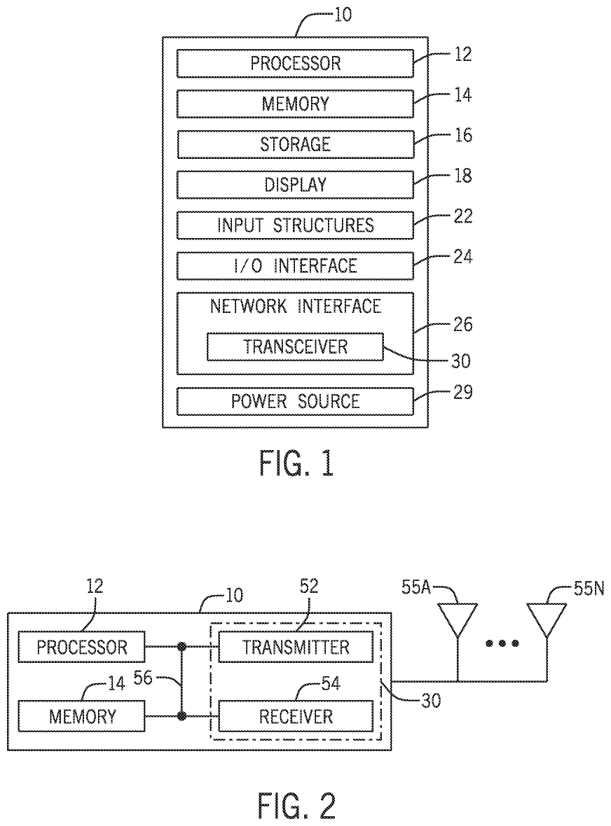

FIG. 1 is a block diagram of an electronic device 10 that uses these systems and methods, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive data between one another. It should be noted that FIG. 1 is merely one example of a particular implementation and is intended to illustrate the types of components that may be present in electronic device 10.

By way of example, the electronic device 10 may include any suitable computing device, including a desktop or notebook computer (e.g., in the form of a MacBook®, MacBook® Pro, MacBook Air®, iMac®, Mac® mini, or Mac Pro® available from Apple Inc. of Cupertino, California), a portable electronic or handheld electronic device such as a wireless electronic device or smartphone (e.g., in the form of a model of an iPhone® available from Apple Inc. of Cupertino, California), a tablet (e.g., in the form of a model of an iPad® available from Apple Inc. of Cupertino, California), a wearable electronic device (e.g., in the form of an Apple Watch® by Apple Inc. of Cupertino, California), and other similar devices. It should be noted that the processor 12 and other related items in FIG. 1 may be generally referred to herein as “data processing circuitry.” Such data processing circuitry may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies. It should be understood that, in some embodiments, the electronic device 10 may not have a display 18, such as in the case of the electronic device 10 being a server, router, communication hub, and so on.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector provided by Apple Inc. of Cupertino, California, a universal serial bus (USB), or other similar connector and protocol. The network interface 26 may include, for example, one or more interfaces for a personal area network (PAN), such as an ultra-wideband (UWB) or a BLUETOOTH® network, for a local area network (LAN) or wireless local area network (WLAN), such as a network employing one of the IEEE 802.11x family of protocols (e.g., WI-FIC)), and/or for a wide area network (WAN), such as any standards related to the Third Generation Partnership Project (3GPP), including, for example, a 3rd generation (3G) cellular network, universal mobile telecommunication system (UMTS), 4th generation (4G) cellular network, long term evolution (LTE®) cellular network, long term evolution license assisted access (LTE-LAA) cellular network, 5th generation (5G) cellular network, and/or New Radio (NR) cellular network, a satellite network, and so on. In particular, the network interface 26 may include, for example, one or more interfaces for using a Release-15 cellular communication standard of the 5G specifications that include the millimeter wave (mmWave) frequency range (e.g., 24.25-300 gigahertz (GHz)) and/or any other cellular communication standard release (e.g., Release-16, Release-17, any future releases) that define and/or enable frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of power, such as a rechargeable lithium polymer (Li-poly) battery and/or an alternating current (AC) power converter. In certain embodiments, the electronic device 10 may take the form of a computer, a portable electronic device, a wearable electronic device, or other type of electronic device.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive data between one another.

The electronic device 10 may include the transmitter 52 and/or the receiver 54 that respectively enable transmission and reception of data between the electronic device 10 and an external device via, for example, a network (e.g., including base stations) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

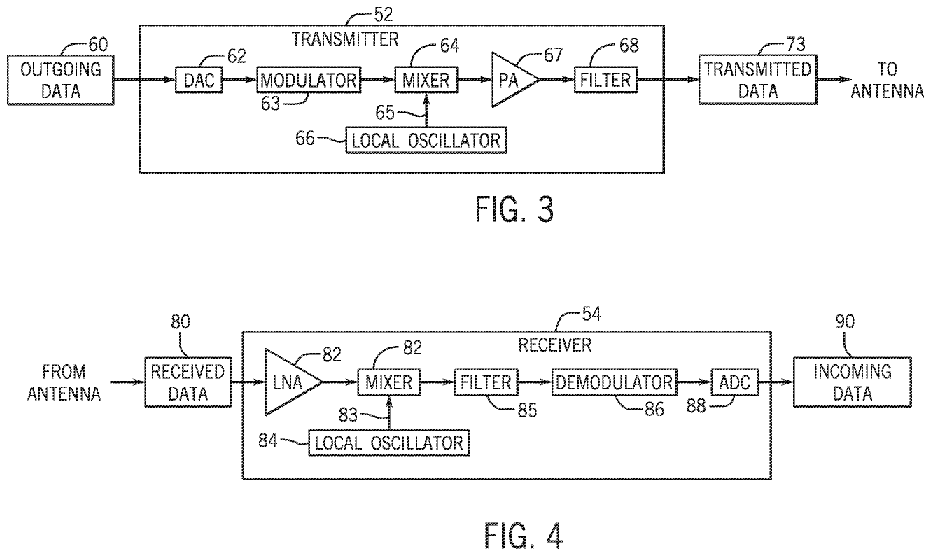

As mentioned above, the transceiver 30 of the electronic device 10 may include a transmitter and a receiver that are coupled to at least one antenna to enable the electronic device 10 to transmit and receive wireless signals. FIG. 3 is a block diagram of a transmitter 52 (e.g., transmit circuitry) that may be part of the transceiver 30, according to embodiments of the present disclosure. As illustrated, the transmitter 52 may receive outgoing data 60 in the form of a digital signal to be transmitted via the one or more antennas 55. A digital-to-analog converter (DAC) 62 of the transmitter 52 may convert the digital signal to an analog signal, and a modulator 63 may combine the converted analog signal with a carrier signal. A mixer 64 may combine the carrier signal with a local oscillator signal 65 (which may include quadrature component signals) from a local oscillator 66 to generate a radio frequency signal. A power amplifier (PA) 67 receives the radio frequency signal from the mixer 64, and may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted data 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter. Additionally, the transmitter 52 may include any suitable additional components not shown, or may not include certain of the illustrated components, such that the transmitter 52 may transmit the outgoing data 60 via the one or more antennas 55. For example, the transmitter 52 may include an additional mixer and/or a digital up converter (e.g., for converting an input signal from a baseband frequency to an intermediate frequency). As another example, the transmitter 52 may not include the filter 68 if the power amplifier 67 outputs the amplified signal in or approximately in a desired frequency range (such that filtering of the amplified signal may be unnecessary).

FIG. 4 is a schematic diagram of a receiver 54 (e.g., receive circuitry) that may be part of the transceiver 30, according to embodiments of the present disclosure. As illustrated, the receiver 54 may receive received data 80 from the one or more antennas 55 in the form of an analog signal. A low noise amplifier (LNA) 81 may amplify the received analog signal to a suitable level for the receiver 54 to process. A mixer 82 may combine the amplified signal with a local oscillator signal 83 (which may include quadrature component signals) from a local oscillator 84 to generate an intermediate or baseband frequency signal. A filter 85 (e.g., filter circuitry and/or software) may remove undesired noise from the signal, such as cross-channel interference. The filter 85 may also remove additional signals received by the one or more antennas 55 that are at frequencies other than the desired signal. The filter 85 may include any suitable filter or filters to remove the undesired noise or signals from the received signal, such as a bandpass filter, a bandstop filter, a low pass filter, a high pass filter, and/or a decimation filter. A demodulator 86 may remove a radio frequency envelope and/or extract a demodulated signal from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received data 80 via the one or more antennas 55. For example, the receiver 54 may include an additional mixer and/or a digital down converter (e.g., for converting an input signal from an intermediate frequency to a baseband frequency).

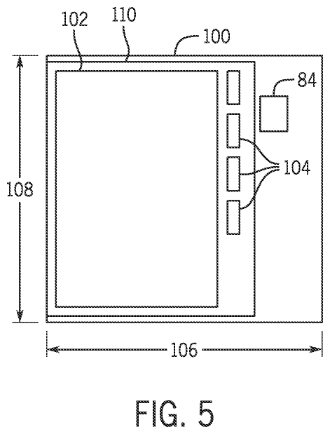

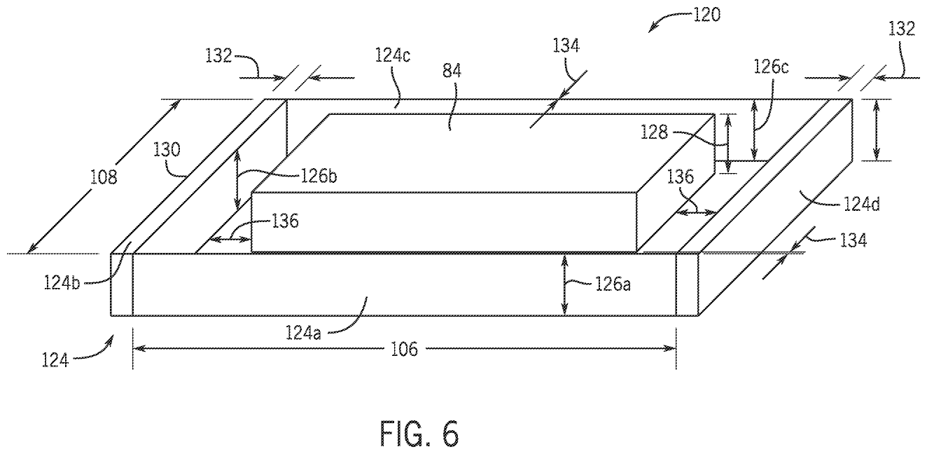

FIG. 5 is a top view of a circuit board 100 having the local oscillator 84 (e.g., a crystal oscillator), a circuit board component 102 (e.g., a WLAN device, a baseband (BB) device), and electronic components 104 (e.g., a capacitor) arranged in different positions along the longitudinal axis 106 and the transverse axis 108 that generally correspond to the area of the circuit board 100. The circuit board component 102 is physically coupled to the circuit board 100 via a coupling material 110. In general, the circuit board component 102 is an electronic device that receives the coupling material 110 (e.g., to couple the circuit board component 102 with an under-fill material) to facilitate coupling between the circuit board component 102 and the circuit board 100. For example, the circuit board component 102 may include a baseband module (e.g., a baseband device) and/or a WiFi module (e.g., a WLAN device) containing switching and low dropout (LDO) power supplies, processing circuitry, passive components (e.g., resistors, inductors, and capacitors), and RF circuitry. As another non-limiting example, the circuit board component 102 may include a power management unit (PMU), other BGA module, major line bundle (MLB), or other components that may receive a coupling material 110. Although only one circuit board component 102 is shown in FIG. 5, any number of circuit board components 102 may be included on the circuit board (e.g., two, three, four, five, or more than five). For example, the local oscillator 84 may be disposed between two circuit board components 102. In any case, in the illustrated embodiment, the electronic components 104 are disposed in between the circuit board component 102 and the local oscillator 84, which may prevent coupling material creep of the coupling material 110 from contaminating the local oscillator 84.

As shown in FIG. 6, a shielded oscillator system 120 may use a contaminant shield system 122 on the circuit board 100 to prevent coupling material creep as well as splatter of the coupling material 110. Furthermore, the contaminant shield system 122 may reduce a footprint of the local oscillator 84 by enabling more flexibility to arrange or orient the electronic components 104 as sufficient coupling material creep or wicking is provided by the contaminant shield system 122. To illustrate this, FIG. 6 is a perspective view of a first example of a shielded oscillator system 120 including a local oscillator 84 and a contaminant shield system 122. As shown in the illustrated embodiment, a first wall 124a, a second wall 124b, a third wall 124c, and a fourth wall 124d (e.g., collectively, the walls 124) are positioned on different sides of the oscillator 84 such that the walls 124 substantially surround the local oscillator 84.

Each of the walls 124 has a height 126 that is a sufficient height for preventing splatter of the coupling material 110 onto the oscillator 84. For example, the height 126 may be approximately 2 mm or less, 1 mm or less, 0.7 mm or less, 0.6 mm or less, 0.5 mm or less, and so on, depending on the constraints of the manufacturing process. As shown in the illustrated embodiment, heights 126a, 126b, 126c, and 126d (e.g., collectively 126) of the walls 124a, 124b, 124c, and 124d is substantially the same. However, in some embodiments, the height 126 of each wall 124 may be any suitable height and/or may be different. For example, if there are certain z-restrictions (e.g., height restrictions) due to stacking of additional circuit boards or other electronic components above the local oscillator 84, it may be advantageous for height 126a, 126b, and 126c of the wall 124a, the wall 124b, and the wall 124c to have a first height, while the height 126d of the wall 124d is a second height greater than the first height 126a. Additionally or alternatively, the height 126d of the wall 124d may have a second height lower than the first height 126a.

As shown in the illustrated embodiment, the height 126 of the walls 124 is substantially equal to the height 128 of the oscillator 84. However, the height 126 of the walls 124 may be any suitable height relative to the height 128 of the oscillator 84. For example, the height 126 of the walls 124 may be greater than or equal to the height 128 of the oscillator 84 such that the walls 124 block or prevent coupling material splatter and or coupling material creep or wicking. Further, in some embodiments (e.g., where the walls 124 of the contaminant shield system 122 are formed of conductive material), the height 126 of the walls 124 may be greater than or equal to the height 128 of the oscillator 84 such that the walls 124 may prevent electromagnetic interference (EMI) for the local oscillator 84. While only four walls 124 are shown, it should be noted that the contaminant shield system 122 may have any suitable number of walls 124 to block coupling material creep, wicking, or splatter, such as two walls 124, three walls 124, four walls 124, five walls 124, or more than five walls 124. A length of the walls 124 (e.g., along the longitudinal axis 106) may be 5 mm or less, 4 mm or less, 3 mm or less, 2.5 mm or less, 2 mm or less and so on and may depend on the size of the oscillator 84 and manufacturing tolerances of pick-and-place devices. A width of the walls 124 (e.g., along the transverse axis 108) may be 3 mm or less, 2.5 mm or less, 2 mm or less, 1.5 mm or less, and so on.

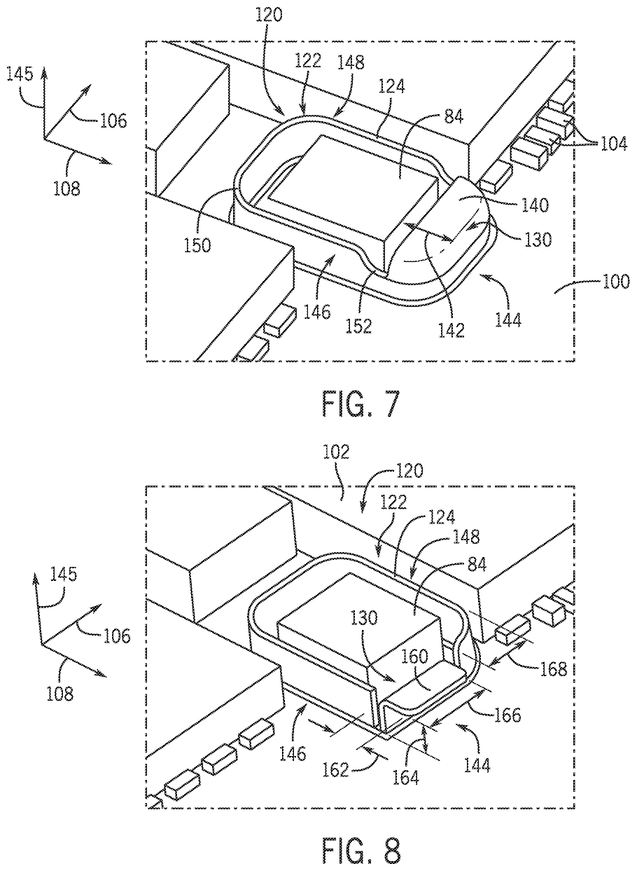

As shown in the illustrated embodiment, the contaminant shield system 122 includes one or more pick-and-place features 130. As described herein, the pick-and-place features 130 generally facilitate the assembly of the contaminant shield system 122 by having suitable dimensions such that the contaminant shield system 122 may be added during pick-and-place assembly operations. For example, pick-and-place devices of the assembly may easily grab the contaminant shield system 122 before positioning the contaminant shield system 122 around the oscillator 84 and/or other electronic components on the circuit board. In the illustrated embodiment, the pick-and-place features 130 are part of the walls 124b and 124d that have a thickness 132 that is greater than the thickness 134 of the walls 124a and 124c. For example, the thickness 132 may be approximately 1 mm or less, 0.9 mm or less, 0.8 mm or less, 0.75 mm or less, 0.5 mm or less, and so on. The thickness 134 may be approximately 0.3 mm or less, 0.2 mm or less, 0.1 mm or less, 0.05 mm or less, and so on. While two of the walls 124 are shown as having the thickness 132 suitable for pick-and-place assembly, it should be noted that any number of the walls 124 may have the thickness 132 suitable for pick-and-place assembly. For example, one, two, three, or all of the walls 124 of the contaminant shield system 122 may have the thickness 132 suitable for pick-and-place assembly. Moreover, in the illustrated embodiment, the walls 124 having the thickness 132 that is suitable for pick-and-place assembly are opposing walls (e.g., the wall 124b and the wall 124c). However, in some embodiments, adjacent walls 124 may also have a thickness 132 that is suitable for pick-and-place assembly. At least in some instances, the walls 124 may have a thickness 132 that is suitable for pick-and-place assembly when the longest dimension of the wall 124 (e.g., along the longitudinal axis 106 and/or the transverse axis 108) is not disposed between the oscillator 84 and a circuit board component 102 that is coupled to a circuit board 100 via the coupling material 110. That is, it is presently recognized that it may be advantageous for the wall 124 to have a thickness 132 that is suitable for pick-and-place assembly when the longest dimension of the wall 124 runs substantially in a direction towards the circuit board component 102 that is coupled to a circuit board 100 via the coupling material 110, rather than the wall 124 that is between the circuit board component 102 and the circuit board 100. In this way, the pick-and-place assembly devices, after picking up the contaminant shield system 122, may have suitable area to place the contaminant shield system 122 without potentially damaging other electronic components, as described in more detail with respect to FIGS. 7 and 8.

As shown in the illustrated embodiment, the local oscillator 84 and the contaminant shield system 122 of the shielded oscillator system 120 are separated by a distance 136. In general, the distance 136 may a suitable distance such that the walls 124 of the contaminant shield system 122 do not contact the local oscillator 84. While the illustrated embodiment shows the distance 136 to be substantially equal on each side of the contaminant shield system 122, the distances 136 on each side of the oscillator 84 may be any suitable distance 136. For example, the distance 136 between the first wall 124a and the local oscillator 84 may be a first distance, and the distance 136 between the second wall 124b and the local oscillator 84 may a second distance, different than the first distance.

It should be noted that references to the oscillator 84 herein, with respect to the arrangement of the contaminant shield system 122 relative to the oscillator 84, may apply to other electronic components that may be sensitive to contamination from the coupling material 110. For example, the contaminant shield system 122 may positioned around a traditional crystal (XTAL), a crystal oscillator (XO), or a thermally compensated crystal oscillator (TCXO), a temperature sensing crystal, a gyroscope, a capacitor, a resistor, a LGA, and so on. For example, if the LGA is contaminated with the coupling material, the contamination may cause mechanical stress and/or partial uncontrolled under-fill may lead to un-even mechanical strain, and ultimately, cracks in the LGA. As such, it may be advantageous to include the contaminant shield system 122 around the LGA. As another non-limiting example, the gyroscope may be sensitive to mechanical stress from the coupling material, thereby causing the gyroscope to operate adversely.

As referred to herein, a “temperature sensing crystal” may include a negative-temperature-coefficient (NTC) thermistor coupled to the temperature sensing crystal (e.g., mounted above the crystal). In general operation of the temperature sensing crystal, NTC signals acquired by the NTC thermistor may be routed out to, ultimately, a processor that uses that temperature reading based on the NTC signals to offset the recorded frequency corresponding to the crystal based on a reference temperature curve, thereby improving the accuracy of the recorded frequencies. It is presently recognized that the contaminant shield system 122 may further improve the accuracy of the recorded frequency.

As described herein, pick-and-place features 130 are generally features having a suitable dimension such that a pick-and-place device can grab the contaminant shield system 122. FIG. 7 is a perspective view of a second example of a shielded oscillator system 120 including a local oscillator 84 and a contaminant shield system 122.

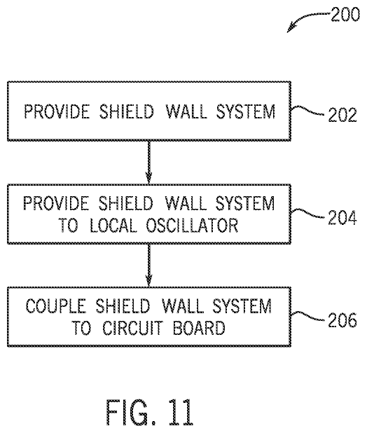

In the illustrated embodiment, the contaminant shield system 122 includes a pick-and-place feature 130 that is a partial lid 140 shape that extends a distance 142 along the transverse axis 108. The distance 142 may be approximately 1 mm or less, 0.9 mm or less, 0.8 mm or less, 0.75 mm or less, 0.5 mm or less, and so on. The partial lid 140 extends from a first side 144 of the contaminant shield system towards the local oscillator 84. Additionally, the partial lid 140 curves away from a vertical direction 145 and along the transverse axis 108. In the illustrated embodiment, the partial lid 140 only extends over a portion of the contaminant shield system 122 along the transverse axis 108, and thus does not cover or overlap the local oscillator 84. At least in some instances, not covering the local oscillator 84 may reduce a likelihood of damage to the local oscillator 84 during assembly (e.g., when the contaminant shield system 122 is positioned around the local oscillator 84, as described in more detail with respect to FIG. 11).

As shown, the partial lid 140 extends the distance 142 from a wall 124 on a first side 144 of the contaminant shield system 122 along the transverse axis 108. The first side 144 generally extends along the longitudinal axis 166. At least in some instances, forming the partial lid 140 such that it extends from the first side 144 along the transverse axis 108, as compared to the second side 146 and/or third side 148, may reduce a likelihood of damaging the local oscillator 84 during assembly.

The wall 124 of the contaminant shield system 122 includes curved corners 150, which may reduce the footprint of the contaminant shield system 122. However, in some embodiments, the walls 124 of the contaminant shield system 122 may form right angles, as generally shown in FIG. 6. Additionally, the wall 124 includes a recess portion 152. In general, the recess portion 152 may form as part of a masking process used to form the partial lid 140.

The illustrated embodiment also includes electronic components 104. As described herein, in some instances, electronic components 104 may be disposed between a local oscillator 84 and the circuit board component 102 to prevent or block coupling material creep. However, as the contaminant shield system 122 is provided around the local oscillator 84, providing the electronic components 104 between the local oscillator 84 and the circuit board components 102 (e.g., on the third side 148 of the contaminant shield system 122) may be avoided since the contaminant shield system 122 may fully protect the local oscillator 84. Instead, the electronic components 104 may be provided in a different position, which may reduce a footprint of components along a particular location of the circuit board 100.

FIG. 8 is a perspective view of a second example of a shielded oscillator system 120 including a local oscillator 84 and a contaminant shield system 122. In the illustrated embodiment, the contaminant shield system 122 includes a pick-and-place feature 130 that is a tab 160 shape that extends a distance 162 along the transverse axis 108. The distance 162 may be approximately 1 mm or less, 0.9 mm or less, 0.8 mm or less, 0.75 mm or less, 0.5 mm or less, and so on. The tab 160 extends from a first side 144 of the contaminant shield system 122 away from the local oscillator 84. Further, the tab 160 has a height 164 along the vertical axis 145 before curving and extending outwards from the local oscillator. In general, the height 164 may be any suitable height such that the tab 160 may prevent coupling material creep, wicking, or splatter. The tab 160 also extends a distance 162 along the longitudinal axis 106 on the first side 144. In general, the tab 160 may extend partially or across the entire wall 124 on the first side 144. However, in some cases the tab 160 may extend along a first portion of the wall 124 on the first side 144, such that a remaining portion 168 of the wall 124 may have a greater height. In this way, the tab 160 may be formed into the wall 124, while providing a suitable height to prevent splatter from a direction where coupling material may be applied. For example, while assembling the illustrated embodiment, the coupling material may be applied to the circuit board component 102 on the third side 148 of the contaminant shield system 122. As such, it may be advantageous that the height 170 along the remaining portion 168 be greater than the height 164 of the tab 160.

In the illustrated embodiment, the partial lid 140 does not cover or overlap the local oscillator 84 along the transverse axis 108, which may reduce a likelihood of damage to the local oscillator 84 during assembly (e.g., when the contaminant shield system 122 is positioned around the local oscillator 84, as described in more detail with respect to FIG. 11).

In a generally similar manner as described with respect to the partial lid 140 of FIG. 7, the tab 160 may extend the distance 162 from a wall 124 on a first side 144 of the contaminant shield system 122 along the transverse axis 108. The first side 144 generally extends along the longitudinal axis 166. At least in some instances, having the tab 160 such that it extends from the first side 144 along the transverse axis 108, as compared to the second side 146 and/or third side 148, may reduce a likelihood of damaging the local oscillator 84 during assembly.

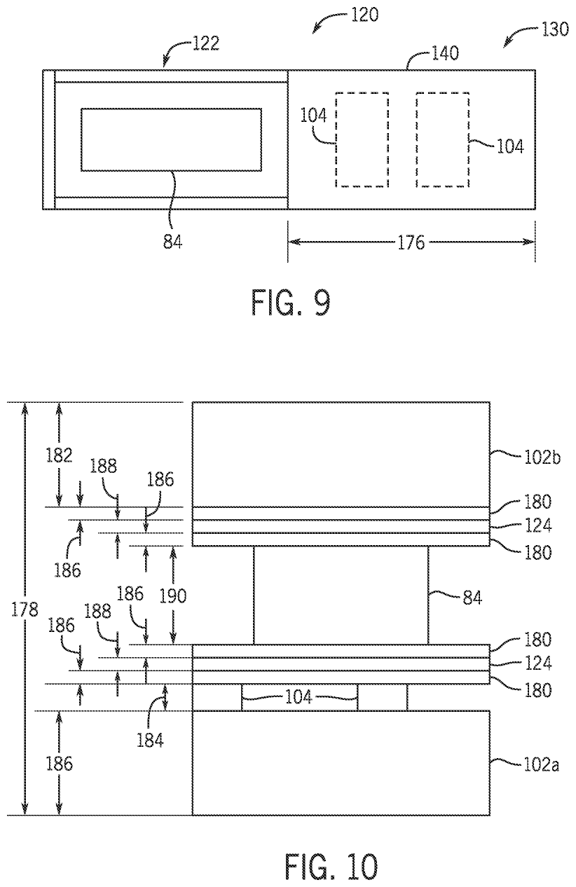

In some embodiments, one or more electronic components 104 may be disposed under the pick-and-place features 130. To illustrate this, FIG. 9 is a perspective view of a first example of a shielded oscillator system 120 including a local oscillator 84 and a contaminant shield system 122 surrounding additional electronic components 104. In general, it is presently recognized that certain electronic components 104 may also perform in unexpected manner when exposed to coupling material (e.g., contaminated with the coupling material 110) due to coupling material creep, wicking, or splatter. Accordingly, the pick-and-place features 130, such as the partial lid 140 may have a suitable length 176 such that the partial lid 140 may also cover one or more electronic components 104. At least in some instances, it may be advantageous not to cover the electronic components 104 with the partial lid 140, while still surrounding the electronic components 104 with the walls 124. For example, it may be desirable to not cover the electronic components 104 if additional circuit boards or other electronic components are stacked on top of the electronic components 104 or there are other height restrictions. As mentioned above, it should be noted that references to the oscillator 84 herein, with respect to the arrangement of the contaminant shield system 122 relative to the oscillator 84, may apply to other electronic components that may be sensitive to contamination from the coupling material 110. For example, the contaminant shield system 122 may positioned around a traditional crystal (XTAL), a crystal oscillator (XO), or a thermally compensated crystal oscillator (TCXO), a temperature sensing crystal, a gyroscope, a capacitor, a resistor, a LGA, and so on.

As described herein, the contaminant shield system 122 may provide certain space-saving benefits, such as reducing the footprint of the local oscillator 84. That is, the contaminant shield system 122 may reduce a total area of components surrounding the local oscillator 84 to prevent coupling material creep, and thus contamination of the local oscillator 84. FIG. 10 is a schematic diagram of a footprint dimension 178 of the components of the circuit board 100, described herein. In general, the footprint dimension 178 corresponds to an arrangement of the circuit board components 102a and 102b (e.g., collectively, circuit board components 102, the electronic component 104, the local oscillator 84, the walls 124 of the contaminant shield system 122, and an adhesive layer 180 (e.g., a soldering layer) that may couple the contaminant shield system 122 to the circuit board 100.

In the depicted arrangement, a first circuit board component 102a includes a width 182 and the first circuit board component 102a is disposed next to electronic components 104, which have a width 184. The electronic components 104 are disposed next to walls 124 sandwiched by an adhesive layer 180. The walls adhesive layer 180 has a width 186 and the walls 124 have a width 188. The walls 124 sandwiched by an adhesive layer 180 are disposed next to the local oscillator 84 including a width 190. The oscillator 84 is sandwiched between another wall 124 sandwiched by an adhesive layer 180, which are disposed next to a second circuit board component 102b. In general, providing the walls 124 around the local oscillator 84 may enable the electronic components 104 to be moved to a different position since the walls 124 may prevent sufficient coupling material creep, wicking, or splatter. As such, the electronic components 104 may be removed, thereby reducing the footprint length 178.

FIG. 11 is a flow chart of a method 200 for assembling the shield oscillator system, according to embodiments of the present disclosure. At block 202, the contaminant shield system 122 is provided. In general, providing the contaminant shield system 122 may include forming the pick-and-place features 130. For example, forming the pick-and-place features 130 may include forming a partial lid 140 using a masking process.

At block 204, the contaminant shield system 122 is provided to the local oscillator 84. In general, providing the contaminant shield system 122 to the local oscillator 84 includes surrounding the local oscillator 84 with the contaminant shield system 122. In some embodiments, the contaminant shield system 122 may be provided or otherwise placed using pick-and-place assembly devices.

At block 206, the contaminant shield system 122 is coupled to the circuit board 100. In some embodiments, providing the contaminant shield system 122 includes adhering the contaminant shield system 122 to the circuit board 100. For example, the contaminant shield system 122 may be soldered to the circuit board 100, thereby forming the adhesive layer 180.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An electronic device comprising:
a circuit board coupled to the electronic device;
a circuit board component coupled to the circuit board via an under-fill material; and
a contaminant shield coupled to the circuit board between the circuit board component and the electronic device, wherein the contaminant shield is configured to prevent the under-fill material from the circuit board component from contaminating the electronic device.

2. The electronic device of claim 1, wherein the contaminant shield is configured to prevent the under-fill material from the circuit board component from contaminating the electronic device through wicking and prevent the under-fill material from the circuit board component from contaminating the electronic device through spattering.

3. The electronic device of claim 1, wherein the contaminant shield has a height sufficient to prevent the under-fill material from the circuit board component from contaminating the electronic device.

4. The electronic device of claim 1, wherein the contaminant shield comprises a first wall having a first thickness, wherein the first wall is disposed between the electronic device and the circuit board component, and wherein the contaminant shield comprises a second wall having a second thickness greater than the first thickness.

5. The electronic device of claim 1, wherein the contaminant shield comprises a plurality of walls, wherein the contaminant shield comprises a partial lid that extends in a direction away from a first wall of the plurality of walls and towards the electronic device.

6. The electronic device of claim 5, comprising one or more electronic components, wherein the one or more electronic components are disposed under the partial lid.

7. The electronic device of claim 1, wherein the contaminant shield comprises a plurality of walls, wherein the contaminant shield comprises a tab that extends in a direction away from a first wall of the plurality of walls and away from the electronic device.

8. The electronic device of claim 1, wherein the contaminant shield is coupled to the circuit board via a solder.

9. The electronic device of claim 1, wherein the contaminant shield is configured to provide electromagnetic interference shielding to the electronic device.

10. The electronic device of claim 1, wherein the electronic device comprises a crystal oscillator.

11. The electronic device of claim 1, wherein the electronic device is a capacitor.

12. The electronic device of claim 1, wherein the electronic device is a gyroscope.

13. A shielded oscillator system, comprising:
a crystal oscillator configured to generate a clock signal; and
a contaminant shield surrounding the crystal oscillator, wherein the contaminant shield comprises a first wall having a first thickness, wherein the first wall is disposed between the crystal oscillator and a circuit board component, and wherein the contaminant shield comprises a second wall having one or more pick-and-place features extending in a direction away from the second wall.

14. The shielded oscillator system of claim 13, wherein the one or more pick-and-place features are disposed on opposing sides of the contaminant shield.

15. The shielded oscillator system of claim 13, wherein the one or more pick-and-place features are on adjected sides of the contaminant shield.

16. The shielded oscillator system of claim 13, wherein a height of the first wall is less than 0.7 mm.

17. The shielded oscillator system of claim 13, wherein a thickness of the first wall is less than 0.3 mm.

18. The shielded oscillator system of claim 13, wherein the one or more pick-and-place features extend towards the crystal oscillator.

19. The shielded oscillator system of claim 18, wherein the one or more pick-and-place features do not cover the crystal oscillator.

20. The shielded oscillator system of claim 13, wherein the one or more pick-and-place features extend away from the crystal oscillator.

21. A method of manufacturing, comprising:
providing a contaminant shield system, wherein the contaminant shield system comprises a plurality of walls and a pick-and-place feature on a first wall of the plurality of walls;
providing the contaminant shield system to a circuit board comprising a crystal oscillator such that the plurality of walls of the contaminant shield system surround the crystal oscillator; and
coupling the contaminant shield system to the circuit board to form a shielded oscillator system.

22. The method of manufacturing of claim 21, wherein providing the contaminant shield system comprises disposing the contaminant shield system next to a circuit board component such that a second wall of the plurality of walls is disposed between the circuit board component and the second wall.

23. The method of manufacturing of claim 21, wherein the contaminant shield system is provided using a pick-and-place device.
